(19) United States
(12) Patent Application Publication
(10) Pub. No.: US 2011/0199395 A1
(43) Pub. Date: Aug. 18, 2011

(54) SYSTEM AND METHOD FOR COMPENSATION OF NON-UNIFORMITIES IN LIGHT EMITTING DEVICE DISPLAYS

(75) Inventors: Arokia Nathan, Cambridge (GB); Gholamreza Chaji, Waterloo (CA); Stefan Alexander, Elmira (CA); Peyman Servati, Vancouver (CA); Richard I-Heng Huang, Waterloo (CA); Corbin Church, Westmount (CA)

(73) Assignee: Ignis Innovation Inc., Kitchener (CA)

(21) Appl. No.: 12/946,601

(22) Filed: Nov. 15, 2010

Related U.S. Application Data
(63) Continuation of application No. 11/402,624, filed on Apr. 12, 2006, now Pat. No. 7,868,857.

(30) Foreign Application Priority Data
Apr. 12, 2005 (CA) CA2504571

(51) Int. Cl. G09G 3/32; G09G 5/10

(52) U.S. Cl. 345/690; 345/82

(57) ABSTRACT

A system and method for operating a display at a constant luminance even as some of the pixels in the display are degraded over time. Each pixel in the display is configured to emit light when a voltage is supplied to the pixel's driving circuit, which causes a current to flow through a light emitting element. Degraded pixels are compensated by supplying their respective driving circuits with greater voltages. The display data is scaled by a compression factor less than one to reserve some voltage levels for compensating degraded pixels. As pixels become more degraded, and require additional compensation, the compression factor is decreased to reserve additional voltage levels for use in compensation.

### CROSS-REFERENCE TO RELATED APPLICATIONS

This application is a continuation-in-part of prior application Ser. No. 11/402,624, filed Apr. 12, 2006, which claims priority to Canadian Patent No. 2,504,571, filed Apr. 12, 2005, each of which is incorporated herein by reference in its entirety.

### FIELD OF THE INVENTION

The present invention relates to display technologies, more specifically a method and system for compensating for non-uniformities of elements in light emitting device displays.

### BACKGROUND

Active-matrix organic light-emitting diode (AMOLED) displays are well known art. Amorphous silicon is, for example, a promising material for AMOLED displays, due to its low cost and vast installed infrastructure from thin film transistor liquid crystal display (TFTLCD) fabrication.

All AMOLED displays, regardless of backplane technology used, exhibit differences in luminance on a pixel to pixel basis, primarily as a result of process or construction inequalities, or from aging caused by operational use over time. Luminance non-uniformities in a display may also arise from natural differences in chemistry and performance from the OLED materials themselves. These non-uniformities must be managed by the AMOLED display electronics in order for the display device to attain commercially acceptable levels of performance for mass-market use.

FIG. 1 illustrates an operational flow of a conventional AMOLED display 10. Referring to FIG. 1, a video source 12 contains luminance data for each pixel and sends the luminance data in the form of digital data 14 to a digital data processor 16. The digital data processor 16 may perform some data manipulation functions, such as scaling the resolution or changing the color of the display. The digital data processor 16 sends digital data 18 to a data driver integrated circuit (IC) 20. The data driver IC 20 converts that digital data 18 into an analog voltage or current 22, which is sent to thin film transistors (TFTs) 26 in a pixel circuit 24. The TFTs 26 convert that voltage or current 22 into another current 28 which flows through an organic light-emitting diode (OLED) 30. The OLED 30 converts the current 28 into visible light 36. The OLED 30 has an OLED voltage 32, which is the voltage drop across the OLED. The OLED 30 also has an efficiency 34, which is a ratio of the amount of light emitted to the current through the OLED.

The digital data 14, analog voltage/current 22, current 28, and visible light 36 all contain the exact same information (i.e. luminance data). They are simply different formats of the initial luminance data that came from the video source 12. The desired operation of the system is for a given value of luminance data from the video source 12 to always result in the same value of the visible light 36.

However, there are several degradation factors which may cause errors on the visible light 36. With continued usage, the TFTs will output lower current 28 for the same input from the data driver IC 20. With continued usage, the OLED 30 will consume greater voltage 32 for the same input current. Because the TFT 26 is not a perfect current source, this will actually reduce the input current 28 slightly. With continued usage, the OLED 30 will lose efficiency 34, and emit less visible light for the same current.

Due to these degradation factors, the visible light output 36 will be less over time, even with the same luminance data being sent from the video source 12. Depending on the usage of the display, different pixels may have different amounts of degradation.

Therefore, there will be an ever-increasing error between the required brightness of some pixels as specified by the luminance data in the video source 12, and the actual brightness of the pixels. The result is that the decreased image will not show properly on the display.

One way to compensate for these problems is to use a feedback loop. FIG. 2 illustrates an operational flow of a conventional AMOLED display 40 that includes the feedback loop. Referring to FIG. 2, a light detector 42 is employed to directly measure the visible light 36. The visible light 36 is converted into a measured signal 44 by the light detector 42. A signal converter 46 converts the measured visible light signal 44 into a feedback signal 48. The signal converter 46 may be an analog-to-digital converter, a digital-to-analog converter, a microcontroller, a transistor, or another circuit or device. The feedback signal 48 is used to modify the luminance data at some point along its path, such as an existing component (e.g. 12, 16, 20, 26, 30), a signal line between components (e.g. 14, 18, 22, 28, 36), or combinations thereof.

Some modifications to existing components, and/or additional circuits may be required to allow the luminance data to be modified based on the feedback signal 48 from the signal converter 46. If the visible light 36 is lower than the desired luminance from video source 12, the luminance signal may be increased to compensate for the degradation of the TFT 26 or the OLED 30. This results in that the visible light 36 will be constant regardless of the degradation. This compensation scheme is often known as Optical Feedback (OFB). However, in the system of FIG. 2, the light detector 42 must be integrated onto a display, usually within each pixel and coupled to the pixel circuitry. Not considering the inevitable issues of yield when integrating a light detector into each pixel, it is desirable to have a light detector which does not degrade itself, however such light detectors are costly to implement, and not compatible with currently installed TFT-LCD fabrication infrastructure.

Therefore, there is a need to provide a method and system which can compensate for non-uniformities in displays without measuring a light signal.

AMOLED displays are conventionally operated according to digital data from a video source. The OLEDs within the display can be programmed to emit light with luminance according to a programming voltage or a programming current. The programming current or programming voltage are conventionally set by a display driver that takes digital data as input and has an analog output for sending the programming current or programming voltage to pixel circuits. The pixel circuits are configured to drive current through OLEDs based on the programming current or programming voltage.

### SUMMARY

It is an object of the invention to provide a method and system that obviates or mitigates at least one of the disadvantages of existing systems.

In accordance with an aspect of the present invention there is provided a system for compensating non-uniformities in a light emitting device display which includes a plurality of pixels and a source for providing pixel data to each pixel circuit. The system includes: a module for modifying the pixel data applied to one or more than one pixel circuit, an estimating module for estimating a degradation of a first pixel circuit based on measurement data read from a part of the first pixel circuit, and a compensating module for correcting the pixel data applied to the first or a second pixel circuit based on the estimation of the degradation of the first pixel circuit.

In accordance with a further aspect of the present invention there is provided a method of compensating non-uniformities in a light emitting device display having a plurality of pixels, including the steps of: estimating a degradation of the first pixel circuit based on measurement data read from a part of the first pixel circuit, and correcting pixel data applied to the first or a second pixel circuit based on the estimation of the degradation of the first pixel circuit.

The present disclosure provides a method of maintaining uniform luminosity of an AMOLED display. The AMOLED display includes an array of pixels having light emitting devices. The light emitting devices are configured to emit light according to digital input from a video source. The video source includes digital data corresponding to a desired luminance of each pixel in the AMOLED display. Over time, aspects within the light emitting devices and their associated driving circuits degrade and require compensation to continue to emit light with the same luminance for a given digital input.

Degradation of the pixels in the light emitting display are compensated by incrementing the digital inputs of the pixels according to a measured or estimated degradation of the pixels. To allow for compensation to occur, the digital input is compressed to a range of values less than an available range. Compressing the digital input is carried out according to a compression factor, which is a number less than one. In an implementation of the present disclosure, the digital inputs are multiplied by the compression factor, which compresses the digital input to a range less than the available range. The remaining portion of the digital range can be used to provide compensation to degraded pixels based on measured or estimated degradation of the pixels. The present disclosure provides methods for setting and adjusting the compression factor to statically or dynamically adjust the compression factor and provide compensation to the display by incrementing the digital signals before the signals are sent to the driving circuits.

The foregoing and additional aspects and embodiments of the present invention will be apparent to those of ordinary skill in the art in view of the detailed description of various embodiments and/or aspects, which is made with reference to the drawings, a brief description of which is provided next.

### BRIEF DESCRIPTION OF THE DRAWINGS

These and other features of the invention will become more apparent from the following description in which reference is made to the appended drawings.

FIG. 1 illustrates a conventional AMOLED system.

FIG. 2 illustrates a conventional AMOLED system that includes a light detector and a feedback scheme that uses the signal from the light detector.

FIG. 3 illustrates a light emitting display system to which a compensation scheme in accordance with an embodiment of the present invention is applied.

FIG. 4 illustrates an example of the light emitting display system of FIG. 3.

FIG. 5 illustrates an example of a pixel circuit of FIG. 5.

FIG. 6 illustrates a further example of the light emitting display system of FIG. 3.

FIG. 7 illustrates an example of a pixel circuit of FIG. 6.

FIG. 8 illustrates an example of modules for the compensation scheme applied to the system of FIG. 4.

FIG. 9 illustrates an example of a lookup table and a compensation algorithm module of FIG. 7.

FIG. 10 illustrates an example of inputs to a TFT-to-pixel circuit conversion algorithm module.

FIG. 11A illustrates an experimental result of a video source outputting equal luminance data for each pixel for a usage time of zero hours.

FIG. 11B illustrates an experimental result of a video source outputting maximum luminance data to some pixels and zero luminance data to other pixels for a usage of time of 1000 hours.

FIG. 11C illustrates an experimental result of a video source outputting equal luminance data for each pixel after some pixels received maximum luminance data and others pixels received zero luminance data for a usage time of 1000 hours when no compensation algorithm is applied.

FIG. 11D illustrates an experimental result of a video source outputting equal luminance data for each pixel after some pixels received maximum luminance data and others pixels received zero luminance data for a usage time of 1000 hours when a constant brightness compensation algorithm is applied.

FIG. 11E illustrates an experimental result of a video source outputting equal luminance data for each pixel after some pixels received maximum luminance data and others pixels received zero luminance data for a usage time of 1000 hours when a decreasing brightness compensation algorithm is applied.

FIG. 12 illustrates an example of a grayscale compression algorithm.

FIG. 13 is a data flow chart showing the compression and compensation of luminosity input data used to drive an AMOLED display.

FIG. 14 is a flowchart illustrating a method for selecting the compression factor according to display requirements and the design of the pixel circuit.

FIG. 15 is a flowchart illustrating a method for selecting the compression factor according to a pre-determined headroom adjustment profile.

FIG. 16 is a flowchart illustrating a method for selecting the compression factor according to dynamic measurements of degradation data exceeding a threshold over a previous compensation.

FIG. 17 is a flowchart illustrating a method for selecting the compression factor according to dynamic measurements of degradation data exceeding a previously measured maximum.

While the invention is susceptible to various modifications and alternative forms, specific embodiments have been shown by way of example in the drawings and will be described in detail herein. It should be understood, however, that the invention is not intended to be limited to the particular forms disclosed. Rather, the invention is to cover all modifications, equivalents, and alternatives falling within the spirit and scope of the invention as defined by the appended claims.

### DETAILED DESCRIPTION

Embodiments of the present invention are described using an AMOLED display which includes a pixel circuit having TFTs and an OLED. However, the transistors in the pixel circuit may be fabricated using amorphous silicon, nano/micro crystalline silicon, poly silicon, organic semiconductors technologies (e.g. organic TFT), NMOS technology, CMOS technology (e.g. MOSFET), or combinations thereof. The transistors may be a p-type transistor or n-type transistor. The pixel circuit may include a light emitting device other than OLED. In the description below, “pixel” and “pixel circuit” may be used interchangeably.

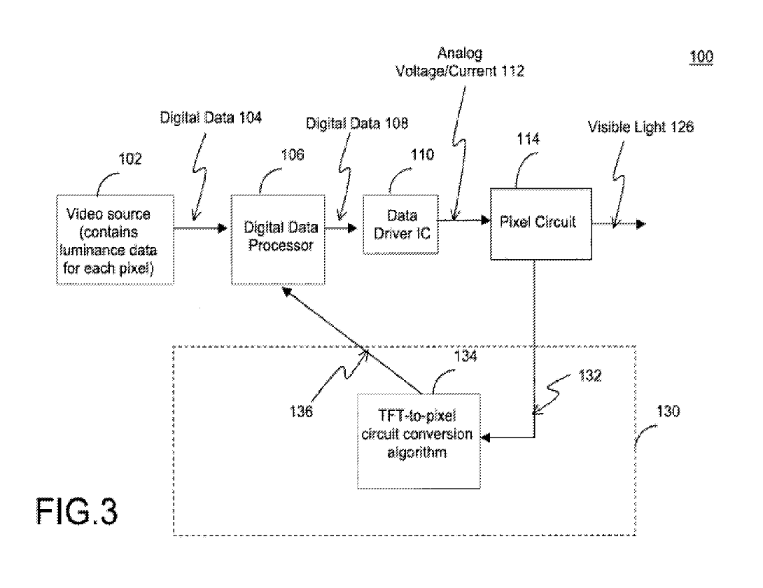

FIG. 3 illustrates the operation of a light emitting display system 100 to which a compensation scheme in accordance with an embodiment of the present invention is applied. A video source 102 contains luminance data for each pixel and sends the luminance data in the form of digital data 104 to a digital data processor 106. The digital data processor 106 may perform some data manipulation functions, such as scaling the resolution or changing the color of the display. The digital data processor 106 sends digital data 108 to a data driver IC 110. The data driver IC 110 converts that digital data 108 into an analog voltage or current 112. The analog voltage or current 112 is applied to a pixel circuit 114. The pixel circuit 114 includes TFTs and an OLED. The pixel circuit 114 outputs a visible light 126 based on the analog voltage or current 112.

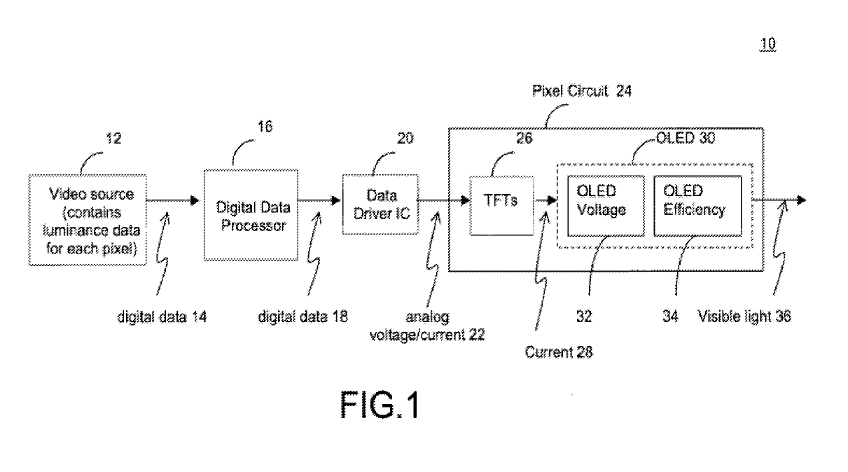

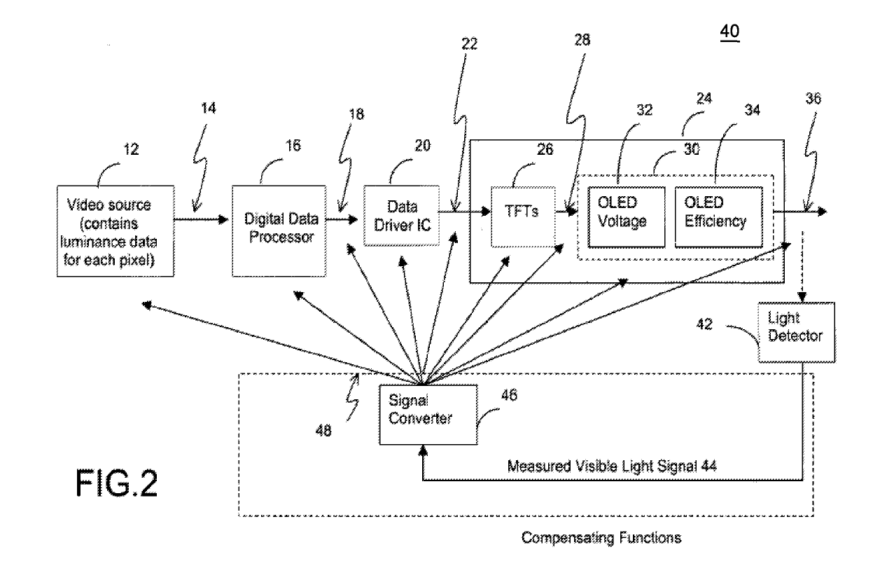

In FIG. 3, one pixel circuit is shown as an example. However, the light emitting display system 100 includes a plurality of pixel circuits. The video source 102 may be similar to the video source 12 of FIGS. 1 and 2. The data driver IC 110 may be similar to the data driver 110 may be similar to the data driver IC 20 of FIGS. 1 and 2.

A compensation functions module 130 is provided to the display. The compensation functions module 130 includes a module 134 for implementing an algorithm (referred to as TFT-to-pixel circuit conversion algorithm) on measurement 132 from the pixel circuit 114 (referred to as degradation data, measured degradation data, measured TFT degradation data, or measured TFT and OLED degradation data), and outputs calculated pixel circuit degradation data 136. It is noted that in the description below, “TFT-to-pixel circuit conversion algorithm module” and “TFT-to-pixel circuit conversion algorithm” may be used interchangeably.

The degradation data 132 is electrical data which represents how much a part of the pixel circuit 114 has been degraded. The data measured from the pixel circuit 114 may represent, for example, one or more characteristics of a part of the pixel circuit 114.

The degradation data 132 is measured from, for example, one or more thin-film-transistors (TFTs), an organic light emitting diode (OLED) device, or a combination thereof. It is noted that the transistors of the pixel circuit 114 are not limited to TFTs, and the light emitting device of the pixel circuit 114 is not limited to an OLED. The measured degradation data 132 may be digital or analog data. The system 100 provides compensation data based on measurement from a part of the pixel circuit (e.g. TFT) to compensate for non-uniformities in the display. The non-uniformities may include brightness non-uniformity, color non-uniformity, or a combination thereof. Factors for causing such non-uniformities may include, but are not limited to, process or construction inequalities in the display, aging of pixels, etc.

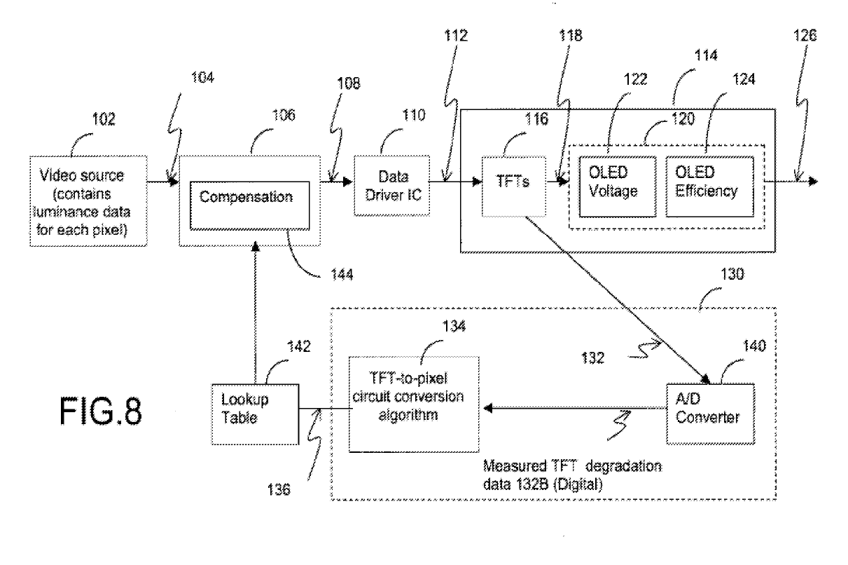

The degradation data 132 may be measured at a regular timing or a dynamically regulated timing. The calculated pixel circuit degradation data 136 may be compensation data to correct non-uniformities in the display. The calculated pixel circuit degradation data 136 may include any parameters to produce the compensation data. The compensation data may be used at a regular timing (e.g. each frame, regular interval, etc.) or dynamically regulated timing. The measured data, compensation data, or a combination thereof may be stored in a memory (e.g. 142 of FIG. 8).

The TFT-to-pixel circuit conversion algorithm module 134 or the combination of the TFT-to-pixel circuit conversion algorithm module 134 and the digital data processor 106 estimates the degradation of the entire pixel circuit based on the measured degradation data 132. Based on this estimation, the entire degradation of the pixel circuit 114 is compensated by adjusting, at the digital data processor 106, the luminance data (digital data 104) applied to a certain pixel circuit(s).

The system 100 may modify or adjust luminance data 104 applied to a degraded pixel circuit or non-degraded pixel circuit. For example, if a constant value of visible light 126 is desired, the digital data processor 106 increases the luminance data for a pixel that is highly degraded, thereby compensating for the degradation.

In FIG. 3, the TFT-to-pixel circuit conversion algorithm module 134 is provided separately from the digital data processor 106. However, the TFT-to-pixel circuit conversion algorithm module 134 may be integrated into the digital data processor 106.

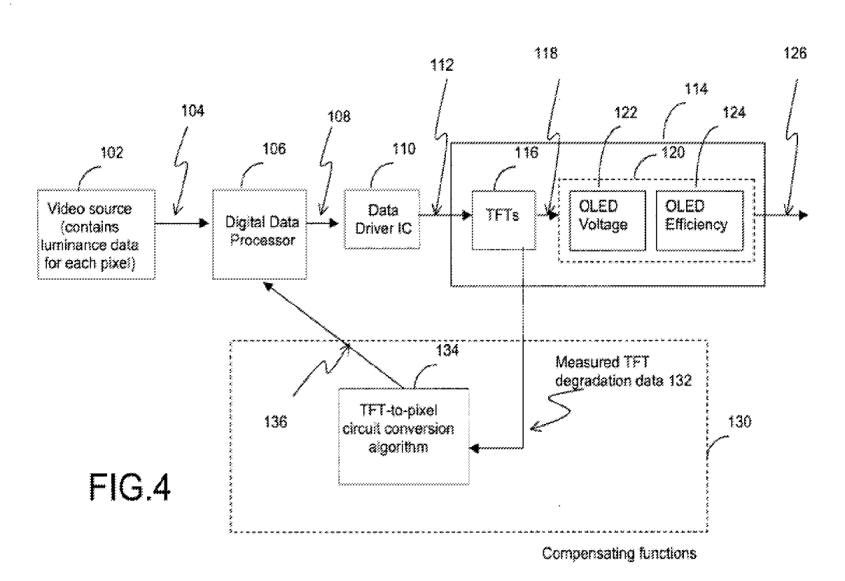

FIG. 4 illustrates an example of the system 100 of FIG. 3. The pixel circuit 114 of FIG. 4 includes TFTs 116 and OLED 120. The analog voltage or current 112 is provided to the TFTs 116. The TFTs 116 convert that voltage or current 112 into another current 118 which flows through the OLED 120. The OLED 120 converts the current 118 into the visible light 126. The OLED 120 has an OLED voltage 122, which is the voltage drop across the OLED. The OLED 120 also has an efficiency 134, which is a ratio of the amount of light emitted to the current through the OLED 120.

The system 100 of FIG. 4 measures the degradation of the TFTs only. The degradation of the TFTs 116 and the OLED 120 are usage-dependent, and the TFTs 116 and the OLED 120 are always linked in the pixel circuit 114. Whenever the TFT 116 is stressed, the OLED 120 is also stressed. Therefore, there is a predictable relationship between the degradation of the TFTs 116, and the degradation of the pixel circuit 114 as a whole. The TFT-to-pixel circuit conversion algorithm module 134 or the combination of the TFT-to-pixel circuit conversion algorithm module 134 and the digital data processor 106 estimates the degradation of the entire pixel circuit based on the TFT degradation only. An embodiment of the present invention may also be applied to systems that monitor both TFT and OLED degradation independently.

The pixel circuit 114 has a component that can be measured. The measurement obtained from the pixel circuit 114 is in some way related to the pixel circuit's degradation.

FIG. 5 illustrates an example of the pixel circuit 114 of FIG. 4. The pixel circuit 114 of FIG. 5 is a 4-T pixel circuit. The pixel circuit 114A includes a switching circuit having TFTs 150 and 152, a reference TFT 154, a dive TFT 156, a capacitor 158, and an OLED 160.

The gate of the switch TFT 150 and the gate of the feedback TFT 152 are connected to a select line Vsel. The first terminal of the switch TFT 154 and the first terminal of the feedback TFT 152 are connected to a data line Idata. The second terminal of the switch TFT 150 is connected to the gate of the reference TFT 154 and the gate of the drive TFT 156. The second terminal of the feedback TFT 152 is connected to the first terminal of the reference TFT 154. The capacitor 158 is connected between the gate of the drive TFT 156 and ground. The OLED 160 is connected between voltage supply Vdd and the drive TFT 156. The OLED 160 may also be connected between drive TFT 156 and ground in other systems (i.e. drain-connected format).

When programming the pixel circuit 114A, Vsel is high and a voltage or current is applied to the data line Idata. The data Idata initially flows through the TFT 150 and charges the capacitor 158. As the capacitor voltage rises, the TFT 154 begins to turn on and Idata starts to flow through the TFTs 152 and 154 to ground. The capacitor voltage stabilizes at the point when all of Idata flows through the TFTs 152 and 154. The current flowing through the TFT 154 is mirrored in the drive TFT 156.

In the pixel circuit 114A, by setting Vsel to high and putting a voltage on Idata, the current flowing into the Idata node can be measured. Alternately, by setting Vsel to high and putting a current on Idata, the voltage at the Idata node can be measured. As the TFTs degrade, the measured voltage (or current) will change, allowing a measure of the degradation to be recorded. In this pixel circuit, the analog voltage/current 112 shown in FIG. 4 is connected to the Idata node. The measurement of the voltage or current can occur anywhere along the connection between the data diver IC 110 and the TFTs 116.

In FIG. 4, the TFT-to-pixel circuit conversion algorithm is applied to the measurement 132 from the TFTs 116. However, current/voltage information read from various places other than TFTs 116 may be usable. For example, the OLED voltage 122 may be included with the measured TFT degradation data 132.

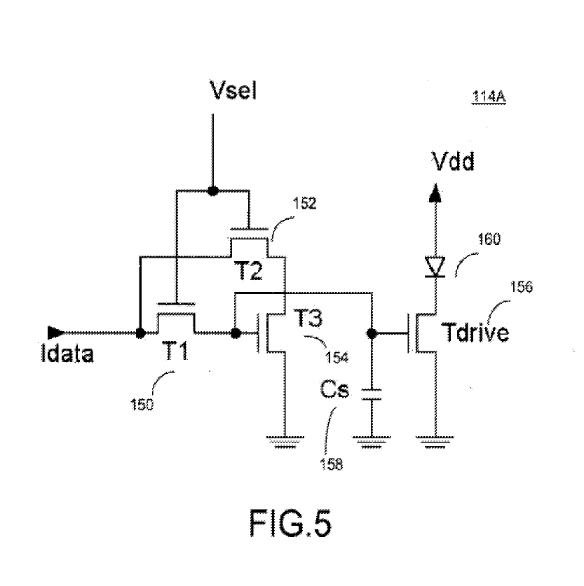

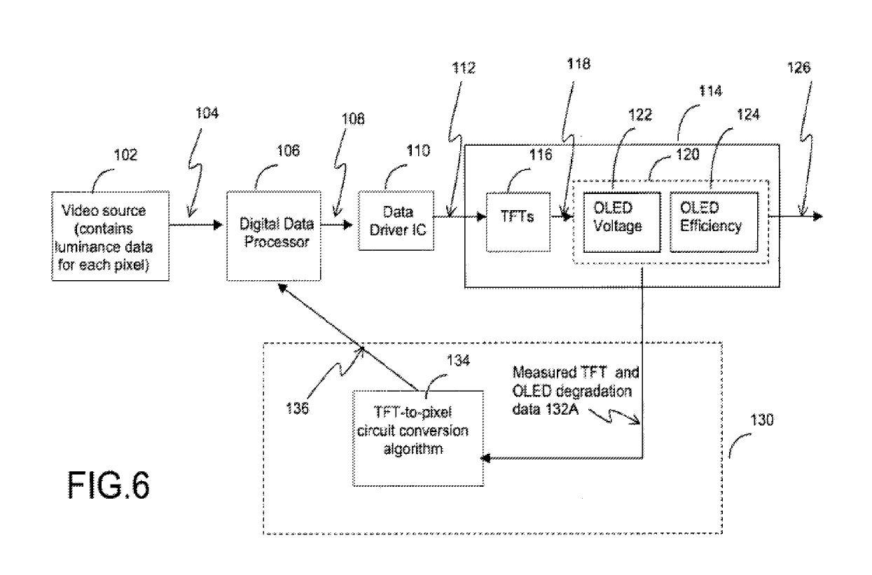

FIG. 6 illustrates a further example of the system 100 of FIG. 3. The system 100 of FIG. 6 measures the OLED voltage 122. Thus, the measured data 132 is related to the TFT 116 and OLED 120 degradation (“measured TFT and OLED voltage degradation data 132A” in FIG. 6). The compensation functions module 130 of FIG. 6 implements the TFT-to-pixel circuit conversion algorithm 134 on the signal related to both the TFT degradation and OLED degradation. The TFT-to-pixel circuit conversion algorithm module 134 or the combination of the TFT-to-pixel circuit conversion algorithm module 134 and the digital data processor 106 estimates the degradation of the entire pixel circuit based on the TFT degradation and the OLED degradation. The TFT degradation and OLED degradation may be measured separately and independently.

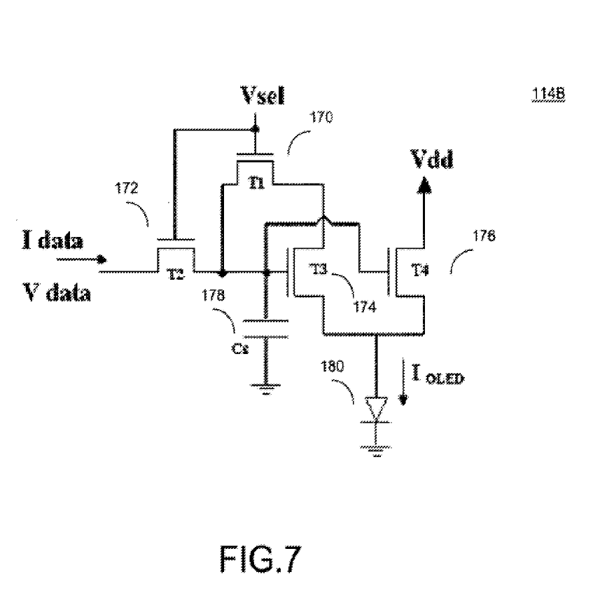

FIG. 7 illustrates an example of the pixel circuit 114 of FIG. 6. The pixel circuit 114B of FIG. 7 is a 4-T pixel circuit. The pixel circuit 114B includes a switching circuit having TFTs 170 and 172, a reference TFT 174, a drive TFT 176, a capacitor 178, and an OLED 180.

The gate of the switch TFT 170 and the gate of the switch TFT 172 are connected to a select line Vsel. The first terminal of the switch TFT 172 is connected to a data line Idata while the first terminal of the switch TFT 170 is connected to the second terminal of the switch TFT 172 which is connected to the gate of the reference TFT 174 and the gate of the dive TFT 176. The second terminal of the switch TFT 170 is connected to the first terminal of the reference TFT 174. The capacitor 178 is connected between the gate of the dive TFT 176 and ground. The first terminal of the dive TFT 176 is connected to voltage supply Vdd. The second terminal of the reference TFT 174 and the second terminal of the drive TFT 176 are connected to the OLED 180.

When programming the pixel circuit 114B, Vsel is high and a voltage or current is applied to the data line Idata. The data Idata initially flows through the TFT 172 and charges the capacitor 178. As the capacitor voltage rises, the TFT 174 begins to turn on and Idata starts to flow through the TFTs 170 and 174 and OLED 180 to ground. The capacitor voltage stabilizes at the point when all of Idata flows through the TFTs 152 and 154. The current flowing through the TFT 154 is mirrored in the drive TFT 156. In the pixel circuit 114A, by setting Vsel to high and putting a voltage on Idata, the current flowing into the Idata node can be measured. Alternately, by setting Vsel to high and putting a current on Idata, the voltage at the Idata node can be measured. As the TFTs degrade, the measured voltage (or current) will change, allowing a measure of the degradation to be recorded. It is noted that unlike the pixel circuit 114A of FIG. 5, the current now flows through the OLED 180. Therefore the measurement made at the Idata node is now partially related to the OLED voltage, which will degrade over time. In the pixel circuit 114B, the analog voltage/current 112 shown in FIG. 6 is connected to the Idata node. The measurement of the voltage or current can occur anywhere along the connection between the data driver IC 110 and the TFTs 116.

Referring to FIGS. 3, 4, and 6, the pixel circuit 114 may allow the current out of the TFTs 116 to be measured, and to be used as the measured TFT degradation data 132. The pixel circuit 114 may allow some part of the OLED efficiency to be measured, and to be used as the measured TFT degradation data 132. The pixel circuit 114 may also allow a node to be charged, and the measurement may be the time it takes for this node to discharge. The pixel circuit 114 may allow any parts of it to be electrically measured. Also, the discharge/charge level during a given time can be used for aging detection.

Referring to FIG. 8, an example of modules for the compensation scheme applied to the system of FIG. 4 is described. The compensation functions module 130 of FIG. 8 includes an analog/digital (A/D) converter 140. The A/D converter 140 converts the measured TFT degradation data 132 into digital measured TFT voltage/current 112 shown in FIG. 4 is connected to the Idata node. The measurement of the voltage or current can occur anywhere along the connection between the data driver IC 110 and the TFTs 116.

In FIG. 4, the TFT-to-pixel circuit conversion algorithm is applied to the measurement 132 from the TFTs 116. However, current/voltage information read from various places other than TFTs 116 may be usable. For example, the OLED voltage 122 may be included with the measured TFT degradation data 132.

FIG. 6 illustrates a further example of the system 100 of FIG. 3. The system 100 of the FIG. 6 measured the OLED voltage 122. Thus, the measured data 132 is related to the TFT 116 and OLED 120 degradation (“measured TFT and OLED voltage degradation data 132A” in FIG. 6). The compensation functions module 130 of FIG. 6 implements the TFT-to-pixel circuit conversion algorithm 134 on the signal related to both the TFT degradation and OLED degradation. The TFT-to-pixel circuit conversion algorithm module 134 or the combination of the TFT-to-pixel circuit conversion algorithm module 134 and the digital data processor 106 estimates the degradation of the entire pixel circuit based on the TFT degradation and the OLED degradation. The TFT degradation and OLED degradation may be measured separately and independently.

FIG. 7 illustrates an example of the pixel circuit 114 of FIG. 6. The pixel circuit 114B of FIG. 7 is a 4-T pixel circuit. The pixel circuit 114B includes a switching circuit having TFTs 170 and 172, a reference TFT 174, a drive TFT 176, a capacitor 178, and an OLED 180.

The gate of the switch TFT 170 and the gate of the switch TFT 172 are connected to a select line Vsel. The first terminal of the switch TFT 172 is connected to a data line Idata while the first terminal of the switch TFT 170 is connected to the second terminal of the switch TFT 172, which is connected to the gate of the reference TFT 174 and the gate of the drive TFT 176. The second terminal of the switch TFT 170 is connected to the first terminal of the reference TFT 174. The capacitor 178 is connected between the gate of the drive TFT 176 and ground. The first terminal of the drive TFT 176 is connected to voltage supply Vdd. The second terminal of the reference TFT 174 and the second terminal of the drive TFT 176 are connected to the OLED 180.

When programming the pixel circuit 114B, Vsel is high and a voltage or current is applied to the data line Idata. The data Idata initially flows through the TFT 172 and charges the capacitor 178. As the capacitor voltage rises, the TFT 174 begins to turn on and Idata starts to flow through the TFTs 170 and 174 and OLED 180 to ground. The capacitor voltage stabilizes at the point when all of Idata flows through the TFTs 152 and 154. The current flowing through the TFT 154 is mirrored in the drive TFT 156. In the pixel circuit 114A, by setting Vsel to high and putting a voltage on Idata, the current flowing into the Idata node can be measured. Alternately, by setting Vsel to high and putting a current on Idata, the voltage at the Idata node can be measured. As the TFTs degrade, the measured voltage (or current) will change, allowing a measure of the degradation to be recorded. It is noted that unlike the pixel circuit 114A of FIG. 5, the current now flows through the OLED 180. Therefore the measurement made at the Idata node is now partially related to the OLED voltage, which will degrade over time. In the pixel circuit 114B, the analog voltage/current 112 shown in FIG. 6 is connected to the Idata node. The measurement of the voltage or current can occur anywhere along the connection between the data driver IC 110 and the TFTs 116.

Referring to FIGS. 3, 4, and 6, the pixel circuit 114 may allow the current out of the TFTs 116 to be measured, and to be used as the measured TFT degradation data 132. The pixel circuit 114 may allow some part of the OLED efficiency to be measured, and to be used as the measured TFT degradation data 132. The pixel circuit 114 may also allow a node to be charged, and the measurement may be the time it takes for this node to discharge. The pixel circuit 114 may allow any parts of it to be electrically measured. Also, the discharge/charge level during a given time can be used for aging detection.

Referring to FIG. 8, an example of modules for the compensation scheme applied to the system of FIG. 4 is described. The compensation functions module 130 of FIG. 8 includes an analog/digital (A/D) converter 140. The A/D converter 140 converts the measured TFT degradation data 132 into digital measured TFT degradation data 132B. The digital measured TFT degradation data 132B is converted into the calculated pixel circuit degradation data 136 at the TFT-to-pixel circuit conversion algorithm module 134. The calculated pixel circuit degradation data 136 is stored in a lookup table 142. Since measuring TFT degradation data from some pixel circuits may take a long time, the calculated pixel circuit degradation data 136 is stored in the lookup table 142 for use.

In FIG. 8, the TFT-to-pixel circuit conversion algorithm 134 is a digital algorithm. The digital TFT-to-pixel circuit conversion algorithm 134 may be implemented, for example, on a microprocessor, an FPGA, a DSP, or another device, but not limited to these examples. The lookup table 142 may be implemented using memory, such as SRAM or DRAM. This memory may be in another device, such as a microprocessor or FPGA, or may be an independent device.

The calculated pixel circuit degradation data 136 stored in the lookup table 142 is always available for the digital data processor 106. Thus, the TFT degradation data 132 for each pixel does not have to be measured every time the digital data processor 106 needs to use the data. The degradation data 132 may be measured infrequently (for example, once every 20 hours, or less). Using a dynamic time allocation for the degradation measurement is another case, more frequent extraction at the beginning and less frequent extraction after the aging gets saturated.

The digital data processor 106 may include a compensation module 144 for taking input luminance data for the pixel circuit 114 from the video source 102, and modifying it based on degradation data for that pixel circuit or other pixel circuit. In FIG. 8, the module 144 modifies luminance data using information from the lookup table 142.

It is noted that the configuration of FIG. 8 is applicable to the system of FIGS. 3 and 6. It is noted that the lookup table 142 is provided separately from the compensating functions module 130, however, it may be in the compensating functions module 130. It is noted that the lookup table 142 is provided separately from the digital data processor 106, however, it may be in the digital data processor 106.

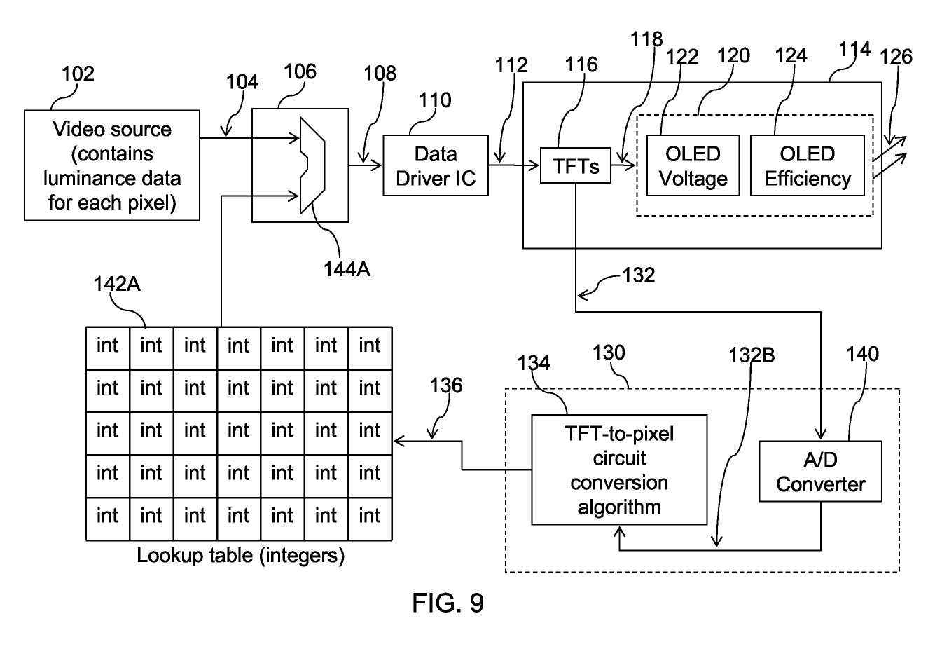

One example of the lookup table 142 and the module 144 of the digital data processor 106 is illustrated in FIG. 9. Referring to FIG. 9, the output of the TFT-to-pixel circuit conversion algorithm module 134 is an integer value. This integer is stored in a lookup table 142A (corresponding to 142 of FIG. 8). Its location in the lookup table 142A is related to the pixel's location on the AMOLED display. Its value is a number, and is added to the digital luminance data 104 to compensate for the degradation.

For example, digital luminance data may be represented to use 8-bits (256 values) for the brightness of a pixel. A value of 246 may represent maximum luminance for the pixel. A value of 128 may represent approximately 50% luminance. The value in the lookup table 142A may be the number that is added to the luminance data 104 to compensate for the degradation. Therefore, the compensation module (144 of FIG. 7) in the digital data processor 106 may be implemented by a digital adder 144A. It is noted that digital luminance data may be represented by any number of bits, depending on the driver IC used (for example, 6-bit, 8-bit, 10-bit, 14-bit, etc.).

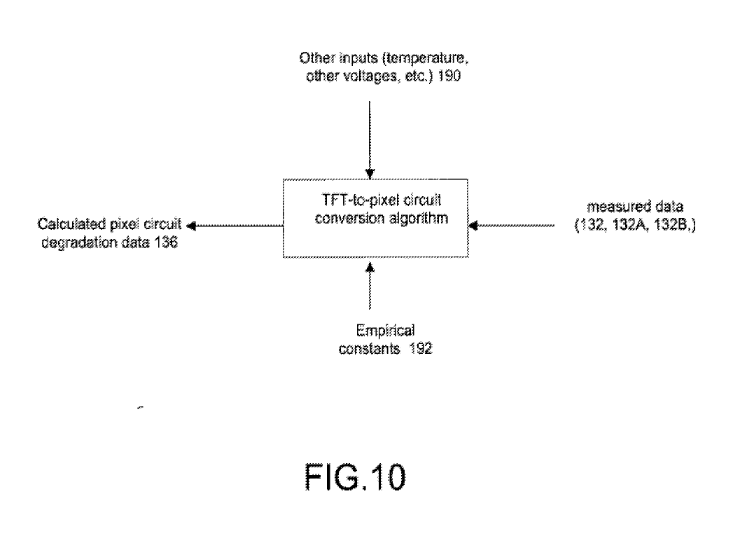

In FIGS. 3, 4, 6, 8, and 9, the TFT-to-pixel circuit conversion algorithm module 134 has the measured TFT degradation data 132 or 132A as an input, and the calculated pixel circuit degradation data 136 as an output. However, there may be other inputs to the system to calculate compensation data as well, as shown in FIG. 10. FIG. 10 illustrates an example of inputs to the TFT-to-pixel circuit conversion algorithm module 134. In FIG. 10, the TFT-to-pixel circuit conversion algorithm module 134 processes the measured data (132 of FIGS. 3, 4, 8, and 9; 132A of FIG. 5; 132B of FIGS. 8 and 9) based on additional inputs 190 (e.g. temperature, other voltages, etc.), empirical constants 192, or combinations thereof.

The additional inputs 190 may include measured parameters such as a voltage reading from current-programming pixels and a current reading from voltage-programming pixels. These pixels may be different from a pixel circuit from which the measured signal is obtained. For example, a measurement is taken from a “pixel under test” and is used in combination with another measurement from a “reference pixel.” As described below, in order to determine how to modify luminance data to a pixel, data from other pixels in the display may be used. The additional inputs 190 may include light measurements, such as measurement of an ambient light in a room. A discrete device or some kind of test structure around the periphery of the panel may be used to measure the ambient light. The additional inputs may include humidity measurements, temperature readings, mechanical stress readings, other environmental stress readings, and feedback from test structures on the panel

It may also include empirical parameters 192, such as the brightness loss in the OLED due to decreasing efficiency (ΔL), the shift in OLED voltage over time (ΔVoled), dynamic effects of Vt shift, parameters related to TFT performance such as Vt, ΔVt, mobility (μ), inter-pixel non-uniformity, DC bias voltages in the pixel circuit, changing gain of current-mirror based pixel circuits, short-term and long-term based shifts in pixel circuit performance, pixel-circuit operating voltage variation due to IR-drop and ground bounce.

Referring to FIGS. 8 and 9, the TFT-to-pixel-circuit conversion algorithm in the module 134 and the compensation algorithm 144 in the digital data processor 106 work together to convert the measured TFT degradation data 132 into a luminance correction factor. The luminance correction factor has information about how the luminance data for a given pixel is to be modified, to compensate for the degradation in the pixel.

In FIG. 9, the majority of this conversion is done by the TFT-to-pixel-circuit conversion algorithm module 134. It calculates the luminance correction values entirely, and the digital adder 144A in the digital data processor 106 simply adds the luminance correction values to the digital luminance data 104. However, the system 100 may be implemented such that the TFT-to-pixel circuit conversion algorithm module 134 calculates only the degradation values, and the digital data processor 106 calculates the luminance correction factor from that data. The TFT-to-pixel circuit conversion algorithm 134 may employ fuzzy logic, neural networks, or other algorithm structures to convert the degradation data into the luminance correction factor.

The value of the luminance correction factor may allow the visible light to remain constant, regardless of the degradation in the pixel circuit. The value of the luminance correction factor may allow the luminance of degraded pixels not to be altered at all; instead, the luminance of the non-degraded pixels to be decreased. In this case, the entire display may gradually lose luminance over time, however the uniformity may be high.

The calculation of a luminance correction factor may be implemented in accordance with a compensation of non-uniformity algorithm, such as a constant brightness algorithm, a decreasing brightness algorithm, or combinations thereof. The constant brightness algorithm and the decreasing brightness algorithm may be implemented on the TFT-to-pixel circuit conversion algorithm module (e.g. 134 of FIG. 3) or the digital data processor (e.g. 106 of FIG. 3). The constant brightness algorithm is provided for increasing brightness of degraded pixels so as to match nondegraded pixels. The decreasing brightness algorithm is provided for decreasing brightness of non-degraded pixels 244 so as to match degraded pixels. These algorithm may be implemented by the TFT-to-pixel circuit conversion algorithm module, the digital data processor (such as 144 of FIG. 8), or combinations thereof. It is noted that these algorithms are examples only, and the compensation of non-uniformity algorithm is not limited to these algorithms.

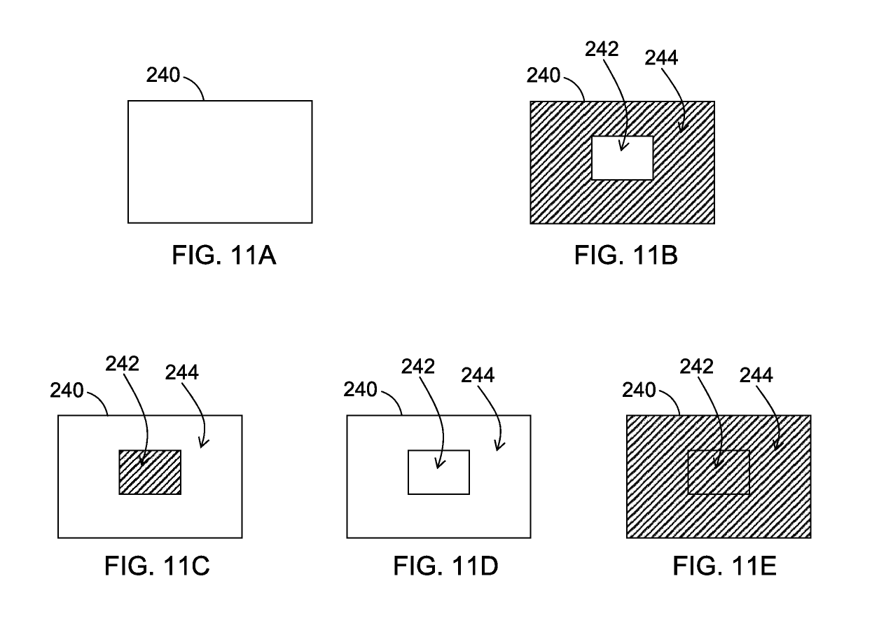

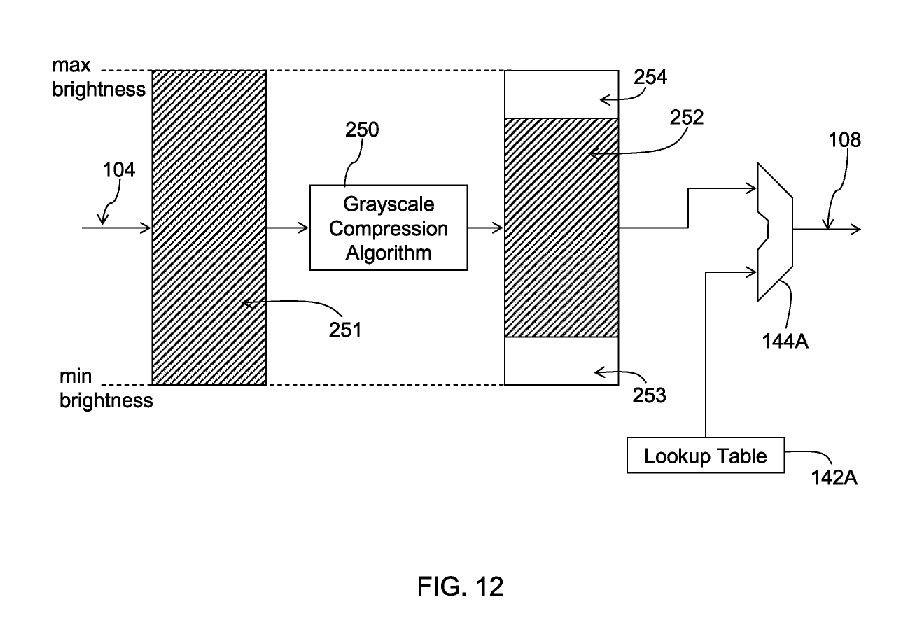

Referring to FIGS. 11A-11E, the experimental results of the compensation of non-uniformity algorithms are described in detail. Under the experiment, an AMOLED display includes a plurality of pixel circuits, and is driven by a system as shown in FIGS. 3, 4, 6, 8 and 9. It is noted that the circuitry to drive the AMOLED display is not shown in FIGS. 11A-11E.

FIG. 11A schematically illustrates an AMOLED display 240 which starts operating (operation period t=0 hour). The video source (102 of FIGS. 3, 4, 7, 8 and 9) initially outputs maximum luminance data to each pixel. No pixels are degraded since the display 240 is new. The result is that all pixels output equal luminance and thus all pixels show uniform luminance.

Next, the video source outputs maximum luminance data to some pixels in the middle of the display as shown in FIG. 11B. FIG. 11B schematically illustrates the AMOLED display 240 which has operated for a certain period where maximum luminance data is applied to pixels in the middle of the display. The video source outputs maximum luminance data to pixels 242, while it outputs minimum luminance data (e.g. zero luminance data) to pixels 244 around the outside of the pixels 242. It maintains this for a long period of time, for example 1000 hours. The result is that the pixels 242 at maximum luminance will have degraded, and the pixels 244 at zero luminance will have no degradation.

At 1000 hours, the video source outputs maximum luminance data to all pixels. The results are different depending on the compensation algorithm used, as shown in FIGS. 11C-11E.

FIGS. 11C schematically illustrates the AMOLED display 240 to which no compensation algorithm is applied. As shown in FIG. 11C, if there was no compensation algorithm, the degraded pixels 242 would have a lower brightness than the nondegraded pixels 244.

FIG. 11D schematically illustrates the AMOLED display 240 to which the constant brightness algorithm is applied. The constant brightness algorithm is implemented for increasing luminance data to degraded pixels, such that the luminance data of the degraded pixels matches that of non-degraded pixels. For example, the increasing brightness algorithm provides increasing currents to the stressed pixels 242, and constant current to the unstressed pixels 244. Both degraded and nondegraded pixels have the same brightness. Thus, the display 240 is uniform. Differential aging is compensated, and brightness is maintained, however more current is required. Since the current to some pixels is being increased, this will cause the display to consume more current over time, and therefore more power over time because power consumption is related to the current consumption.

FIG. 11E schematically illustrates the AMOLED display 240 to which the decreasing brightness algorithm is applied. The decreasing brightness algorithm decreases luminance data to nondegraded pixels, such that the luminance data of the nondegraded pixels match that of degraded pixels. For example, the decreasing brightness algorithm provides constant OLED current to the stressed pixels 242, while decreasing current to the unstressed pixels 244. Both degraded and non-degraded pixels have the same brightness. Thus, the display 240 is uniform. Differential aging is compensated, and it requires a lower Vsupply, however brightness decrease over time. Because this algorithm does not increase the current to any of the pixels, it will not result in increased power consumption.

Referring to FIG. 3, components, such as the video source 102 and the data driver IC 110, may use only 8-bits, or 256 discrete luminance values. Therefore if the video source 102 outputs maximum brightness (a luminance value of 255), there is no way to add any additional luminance, since the pixel is already at the maximum brightness supported by the components in the system. Likewise, if the video source 102 outputs minimum brightness (a luminance value of 0), there is no way to subtract any luminance. The digital data processor 106 may implement a grayscale compression algorithm to reserve some grayscales. FIG. 12 illustrates an implementation of the digital data processor 106 which includes a grayscale compression algorithm module 250. The grayscale compression algorithm 250 takes the video signal represented by 256 luminance values, and transforms it to use less luminance values. For example, instead of minimum brightness represented by grayscale 0, minimum brightness may be represented by grayscale 50. Likewise, maximum brightness may be represented by grayscale 200. In this way, there are some grayscales reserved for future increase and decrease. It is noted that the shift in grayscales does not reflect the actual expected shift in grayscales.

According to the embodiments of the present invention, the scheme of estimating (predicting) the degradation of the entire pixel circuit and generating a luminance correction factor ensures uniformities in the display. According to embodiments of the present invention, the aging of some components or entire circuit can be compensated, thereby ensuring uniformity of the display.

According to the embodiments of the present invention, the TFT-to-pixel circuit conversion algorithm allows for improved display parameters, for example, including constant brightness uniformity and color uniformity across the panel over time. Since the TFT-to-pixel circuit conversion algorithm takes in additional parameters, for example, temperature and ambient light, any changes in the display due to these additional parameters may be compensated for.

The TFT-to-Pixel circuit conversion algorithm module (134 of FIGS. 3, 4, 6, 8 and 9), the compensation module (144 of FIG. 8, 144A of FIG. 9, the compensation of non-uniformity algorithm, the constant brightness algorithm, the decreasing brightness algorithm and the grayscale compression algorithm may be implemented by any hardware, software or a combination of hardware and software having the above described functions. The software code, instructions and/or statements, either in its entirety or a part thereof, may be stored in a computer readable memory. Further, a computer data signal representing the software code, instructions and/or statements, which may be embedded in a carrier wave may be transmitted via a communication network. Such a computer readable memory and a computer data signal and/or its carrier are also within the scope of the present invention, as well as the hardware, software and the combination thereof.

Referring again to FIG. 3, which illustrates the operation of the light emitting display system 100 by applying a compensation algorithm to digital data 104. In particular, FIG. 3 illustrates the operation of a pixel in an active matrix organic light emitting diode (AMOLED) display. The display system 100 includes an array of pixels. The video source 102 includes luminance input data for the pixels. The luminance data is sent in the form of digital input data 104 to the digital data processor 106. The digital input data 104 can be eight-bit data represented as integer values existing between 0 and 255, with greater integer values corresponding to higher luminance levels. The digital data processor 106 can optionally manipulate the digital input data 104 by, for example, scaling the resolution of the video source 102 to a native screen resolution, adjusting the color balance, or applying a gamma correction to the video source 102. The digital data processor 106 can also apply degradation corrections to the digital input data 104 based on degradation data 136. Following the manipulations, the digital data processor 106 sends the resulting digital data 108 to the data driver integrated circuit (IC) 110. The data driver IC 110 converts the digital data 108 into the analog voltage or current output 112. The data driver IC 110 can be implemented, for example, as a module including a digital to analog converter. The analog voltage or current 112 is provided to the pixel circuit 114. The pixel circuit 114 can include an organic light emitting diode (OLED) and thin film transistors (TFTs). One of the TFTs in the pixel circuit 114 can be a drive TFT that applies a drive current to the OLED. The OLED emits visible light 126 responsive to the drive current flowing to the OLED. The visible light 126 is emitted with a luminance related to the amount of current flowing to the OLED through the drive TFT.

In a configuration where the analog voltage or current 112 is a programming voltage, the drive TFT within the pixel circuit 114 can supply the OLED according to the analog voltage or current 112 by, for example, biasing the gate of the drive TFT with the programming voltage. The pixel circuit 114 can also operate where the analog voltage or current 112 is a programming current applied to each pixel rather than a programming voltage. A display system 100 utilizing programming currents can use current minors in each pixel circuit 114 to apply a drive current to the OLED through the drive TFT according to the programming current applied to each pixel.

The luminance of the emitted visible light 126 is affected by aspects within the pixel circuit 114 including the gradual degradation of hardware within the pixel circuit 114. The drive TFT has a threshold voltage, and the threshold voltage can change over time due to aging and stressing of the drive TFT. The luminance of the emitted visible light 126 can be influenced by the threshold voltage of the drive TFT, the voltage drop across the OLED, and the efficiency of the OLED. The efficiency of the OLED is a ratio of the luminance of the emitted visible light 126 to the drive current flowing through the OLED. Furthermore, the degradation can generally be non-uniform across the display system 100 due to, for example, manufacturing tolerances of the drive TFTs and OLEDs and differential aging of pixels in the display system 100. Non-uniformities in the display 100 are generally referred to as display mura or defects. In a display 100 with an array of OLEDs having uniform light emitting efficiency and threshold voltages driven by TFTs having uniform gate threshold voltages, the luminance of the display will be uniform when all the pixels in the display are programmed with the same analog voltage or current 112. However, as the OLEDs and TFTs in each pixel age and the degradation characteristics change, the luminance of the display ceases to be uniform when programmed the same.

The degradation can be compensated for by increasing the amount of drive current sent through the OLED in the pixel circuit 114. According to an implementation of the present disclosure, compensation for the degradation of the display 100 can be carried out by adjusting the digital data 108 output from the digital data processor 106. The digital data processor 106 receives the degradation data 136 from the compensation module 130. The compensation module 130 receives degradation data 132 based on measurements of parameters within the pixel circuit 114. Alternatively, the degradation data 132 sent to the compensation module 130 can be based on estimates of expected performance of the hardware aspects within the pixel circuit 114. The compensation module 130 includes the module 134 for implementing the algorithm 134, such as the TFT-to-pixel circuit conversion algorithm. The degradation data 132 can be electrical data that represents how much a hardware aspect of the pixel circuit 114 has been degraded. The degradation data 132 measured or estimated from the pixel circuit 114 can represent one or more characteristics of the pixel circuit 114.

In a configuration where the analog voltage or current 112 is a programming voltage, the programming voltage is generally determined by the digital input data 104, which is converted to a voltage in the data driver IC 110. The present disclosure provides a method of compensating for non-uniform characteristics in each pixel circuit 114 that affect the luminance of the emitted visible light 126 from each pixel. Compensation is performed by adjusting the digital input data 104 in the digital data processor 106 before the digital data 108 is passed to the data driver IC 110.

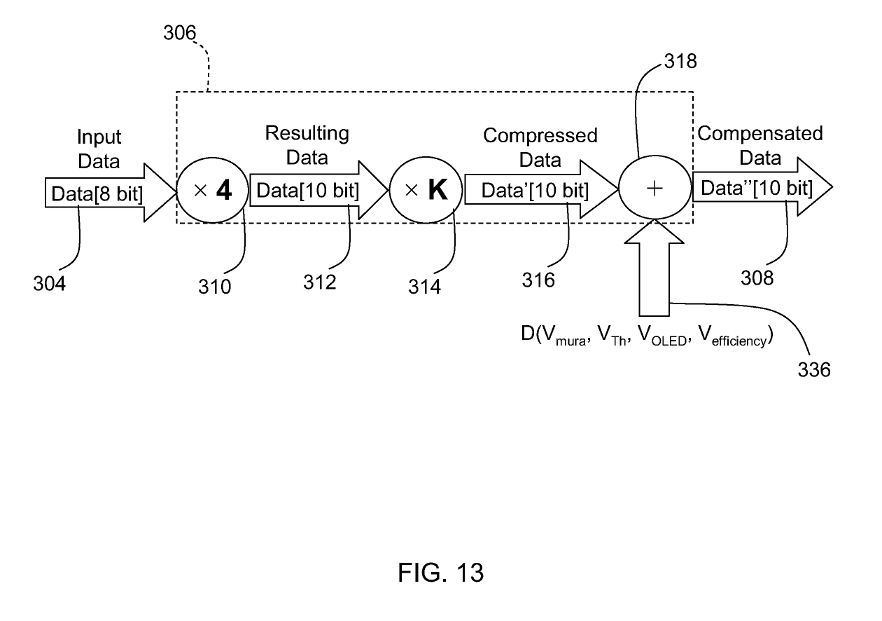

FIG. 13 is a data flow chart showing the compression and compensation of luminosity input data 304 used to drive an AMOLED display. The data flow chart shown in FIG. 13 includes a digital data processor block 306 that can be considered an implementation of the digital data processor 106 shown in FIG. 3. Referring again to FIG. 13, a video source provides the luminosity input data 304. The input data 304 is a set of eight-bit integer values. The input data 304 includes integer values that exist between 0 and 255, with the values representing 256 possible programmable luminosity values of the pixels in the AMOLED display. For example, 255 can correspond to a pixel programmed with maximum luminance, and 127 can correspond to a pixel programmed with roughly half the maximum luminance. The input data 304 is similar to the digital input data 104 shown in FIG. 3. Referring again to FIG. 13, the input data 304 is sent to the digital data processor block 304. In the digital data processor block 304, the input data 304 is multiplied by four (310) in order to translate the eight-bit input data 304 to ten-bit resulting data 312. Following the multiplication by four (310), the resulting data 312 is a set of ten-bit integers existing between 0 and 1020.

By translating the eight-bit input data 304 to the ten-bit resulting data 312, the resulting data 312 can be manipulated for compensation of luminance degradation with finer steps than can be applied to the eight-bit input data 304. The ten-bit resulting data 312 can also be more accurately translated to programming voltages according to a gamma correction. The gamma correction is a non-linear, power law correction as is appreciated in the art of display technology. Applying the gamma correction to the input data can be advantageous, for example, to account for the logarithmic nature of the perception of luminosity in the human eye. According to an aspect of the present disclosure, multiplying the input data 304 by four (310) translates the input data 304 into a higher quantized domain. While the present disclosure includes multiplying by four (310), in an implementation the input data 304 can be multiplied by any number to translate the input data 310 into a higher quantized domain. The translation can advantageously utilize multiplication by a power of two, such as four, but the present disclosure is not so limited. Additionally, the present disclosure can be implemented without translating the input data 304 to a higher quantized domain.

The resulting data 312 is multiplied by a compression factor, K (314). The compression factor, K, is a number with a value less than one. Multiplying the resulting data 312 by K (314) allows for scaling the ten-bit resulting data 312 into compressed data 316. The compressed data 316 is a set of ten-bit integers having values ranging from 0 to the product of K and 1020. Next, the compressed data 316 is compensated for degradations in the display hardware (318). The compressed data 316 is compensated by adding additional data increments to the integers corresponding to the luminance of each pixel (318). The compensation for degradation is performed according to degradation data 336 that is sent to the digital data processor block 306. The degradation data 336 is digital data representing an amount of compensation to be applied to the compressed data 316 within the digital data processor block 306 according to degradations in the display hardware corresponding to each pixel. Following the compensation for degradations (318), compensated data 308 is output. The compensated data 208 is a set of ten-bit integer values with possible values between 0 and 1023. The compensated data 308 is similar in some respects to the digital data 108 output from the digital data processor 106 in FIG. 3. Referring again to FIG. 13, the compensated data 308 is supplied to a display driver, such as a display driver incorporating a digital to analog converter, to create programming voltages for pixels in the AMOLED display.

The degradations in the display hardware can be from mura defects (non-uniformities), from the OLED voltage drop, from the voltage threshold of the drive TFT, and from changes in the OLED light emitting efficiency. The degradations in the display hardware each generally correspond to an additional increment of voltage that is applied to the pixel circuit in order to compensate for the degradations. For a particular pixel, the increments of additional voltage necessary to compensate for the hardware degradations can be referred to as: Vₘᵤᵣₐ, V_{Th}, V_{OLED}, and V_{efficiency}. Each of the hardware degradations can be mapped to corresponding increments in data steps according to a function of Vₘᵤᵣₐ, V_{Th}, V_{OLED}, V_{efficiency}, D(Vₘᵤᵣₐ, V_{Th}, V_{OLED}, V_{efficiency}). For example, the relationship can be given by Expression 1: D(Vₘᵤᵣₐ, V_{Th}, V_{OLED}, V_{efficiency})=int[(2^{nBits}−1) (Vₘᵤᵣₐ+V_{Th}+V_{OLED}+V_{efficiency})/V_{Max}], where nBits is the number of bits in the data set being compensated and V_{Max} is the maximum programming voltage. In Expression 1, int[ ] is a function that evaluates the contents of the brackets and returns the nearest integer. The degradation data 336 sent to the digital data processor block 306 can be digital data created according to the relationship for D(Vₘᵤᵣₐ, V_{Th}, V_{OLED}, V_{efficiency}) provided in Expression 1. In an implementation of the present disclosure, the degradation data 336 can be an array of digital data corresponding to an amount of compensation to be applied to the compressed data of each pixel in an AMOLED display. The array of digital data is a set of offset increments that can be applied to the compressed data by adding the offset increments to the compressed data of each pixel or by subtracting the offset increments from the compressed data of each pixel. The set of offset increments can generally be a set of digital data with entries corresponding to an amount of compensation needed to be applied to each pixel in the AMOLED display. The amount of compensation can be the amount of increments in data steps needed to compensate for a degradation according to Expression 1. In a configuration, locations in the array of the degradation data 336 can correspond to locations of pixels in the AMOLED display.

For example, Table 1 below provides a numerical example of the compression of input data according to FIG. 13. Table 1 provides example values for a set of input data 304 following the multiplication by four (310) and the multiplication by K (314). In the example provided in Table 1, K has a value of 0.75. In Table 1, the first column provides example values of integer numbers in the set of input data 304. The second column provides example values of integer numbers in the set of resulting data 312 created by multiplying the corresponding input data values by four (310). The third column provides example values of numbers in the set of compressed data 316 created by multiplying the corresponding values of the resulting data 312 by K, where K has an example value of 0.75. The final column is the output voltage corresponding to the example compressed data 316 shown in the third column when no compensation is applied. The final column is created for an example display system having a maximum programming voltage of 18 V. In the numerical example illustrated in Table 1, the programming output voltage corresponding to the input data with the maximum input of two-hundred fifty-five is more than 4.5 V below the maximum voltage. The 4.5 V can be considered the compensation budget of the display system, and can be referred to as the voltage headroom, V_{headroom}. According to an aspect of the present disclosure, the 4.5 V is used to provide compensation for degradation of pixels in the AMOLED display.

TABLE 1
Numerical Example of Input Data Compression

| | | | Output Voltage |
|---|---|---|---|
| | Resulting Data | Compressed Data | (without degradation |
| Input Data | (×4) | (×0.75) | compensation) |
| 255 | 1020 | 765 | 13.46 V |
| 254 | 1016 | 762 | 13.40 V |
| 253 | 1012 | 759 | 13.35 V |
| . . . | . . . | . . . | . . . |
| 2 | 8 | 6 | 0.10 V |
| 1 | 4 | 3 | 0.05 V |
| 0 | 0 | 0 | 0.00 V |

According to an implementation of the present disclosure, the amount of voltage available for providing compensation degradation is V_{headroom}. An amount of V_{headroom} can be advantageously reserved to compensate for a degradation of a pixel in an AMOLED display with the most severe luminance degradation. By reserving an amount of V_{headroom} to compensate for the most severely degraded pixel, the relative luminosity of the display can be advantageously maintained. The required amount of V_{headroom} to compensate for the pixel in an AMOLED display with a maximum amount of degradation is given by Expression 2: V_{headroom}=max[Vₘᵤᵣₐ+V_{Th}+V_{OLED}+V_{efficiency}]. In Expression 2, Vₘᵤᵣₐ, V_{Th}, V_{OLED}, and V_{efficiency} can be an array of values corresponding to the amount of additional voltage necessary to compensate the pixels in the display, and the entries in the arrays of values can correspond to individual pixels in the display. That is, Vₘᵤᵣₐ can be an array of voltages required to compensate display mura or non-uniform defects; V_{Th} can be an array of voltage thresholds of drive TFTs of pixels in the display; V_{OLED} can be an array of OLED voltages of the pixels in the display; and V_{efficiency} can be an array of voltages required to compensate for OLED efficiency degradations of pixels in the display. In Expression 2, max[ ] is a function evaluating an array of values in the brackets and returning the maximum value in the array.

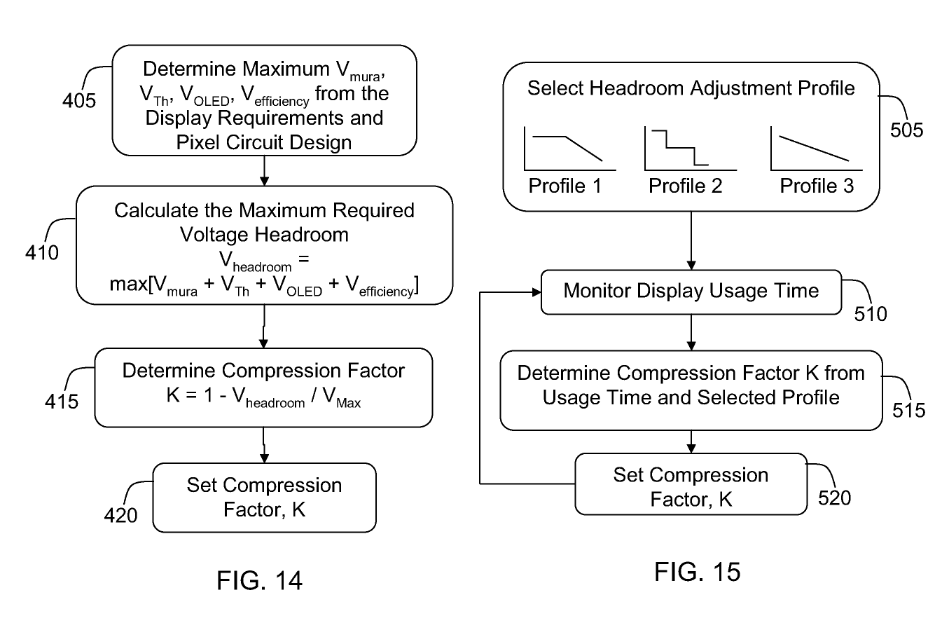

As can be appreciated with reference to FIG. 13 and Table 1, the choice of K affects the amount of V_{headroom} available to compensate for degradations in the display. Choosing a lower value of K leads to a greater amount of V_{headroom}. In a configuration of the present disclosure where the need for compensation increases over time due to aging of the display, the value of K can be advantageously decreased over time according to the degradation of the display over time. Decreasing K enables uniformity compensation across the display such that pixels receiving the same digital input data actually emit light with the same luminance, but the uniformity compensation comes at the cost of overall luminance reduction for the entire display. FIGS. 14 through 17 provide methods for selecting and adjusting K.

FIG. 14 is a flowchart illustrating a method for selecting the compression factor according to display requirements and the design of the pixel circuit. In operation of the method illustrated by the flowchart in FIG. 14, the display requirements and pixel circuit design of a display are analyzed to estimate maximum values of Vₘᵤᵣₐ, V_{Th}, V_{OLED}, and V_{efficiency} for the pixels in the display (405). The estimation (405) can be carried out based on, for example, empirical data from experimental results related to the aging of displays incorporating pixel circuits similar to the pixel circuit in the display 100. Alternatively, the estimation (405) can be carried out based on numerical models or software-based simulation models of anticipated performances of the pixel circuit in the display 100. The estimation (405) can also account for an additional safety margin of headroom voltage to account for statistically predictable variations amongst the pixel circuits in the display 100. Responsive to the estimation (405), the required voltage headroom is calculated (410). The required voltage headroom, V_{headroom}, is calculated according to Expression 2. Once V_{headroom} is calculated, the compression factor, K, is calculated (415) according to Expression 3: K=1−V_{headroom}/V_{Max}, where V_{Max} is a maximum programming voltage for the display 100. The compression factor, K, is then set (420) for use in the compression and compensation algorithm, such as the compression algorithm illustrated in the data flow chart in FIG. 13.

FIG. 15 is a flowchart illustrating a method for selecting the compression factor according to a pre-determined headroom adjustment profile. A headroom adjustment profile is selected (505). The first block 505 in the flowchart in FIG. 15 graphically illustrates three possible headroom adjustment profiles as profile 1, profile 2, and profile 3. The profiles illustrated are graphs of K versus time. The time axis can be, for example, a number of hours of usage of the display 100. In all three profiles K decreases over time. By decreasing K over time, an additional amount of voltage (V_{headroom}) is available for compensation. The example profiles in the first block 505 include profile 1, which maintains K at a constant level until a time threshold is reached and K decreases linearly with usage time thereafter. Profile 2 is a stair step profile, which maintains K at a constant level for a time, and then decreases K to a lower value, when it is maintained until another time, at which point it is decreased again. Profile 3 is a linear decrease profile, which provides for K to gradually decrease linearly with usage time. The profile can be selected by a user profile setting according to a user's preferences for the compensation techniques employed over the life of the display. For example, a user may want to maintain an overall maximum luminance for the display for a specific amount of usage hours before dropping the luminance. Another user may be fine with gradually dropping the luminance from the beginning of the display's lifetime.

Once an headroom adjustment profile is selected (505), the display usage time is monitored (510). At a given usage time, the value of the compression factor, K, is determined according to the usage time and selected profile (515). The compression factor, K, is then set (520), and the display usage time continues to be monitored (510). After K is set (520), K can be used in the compression and compensation algorithm, such as the compression algorithm illustrated in the data flow chart in FIG. 13. According to an aspect of the present disclosure, the method of setting and adjusting K shown in FIG. 15 is a dynamic method of setting and adjusting K, because the value of K is updated over time according to the usage time of the display 100.

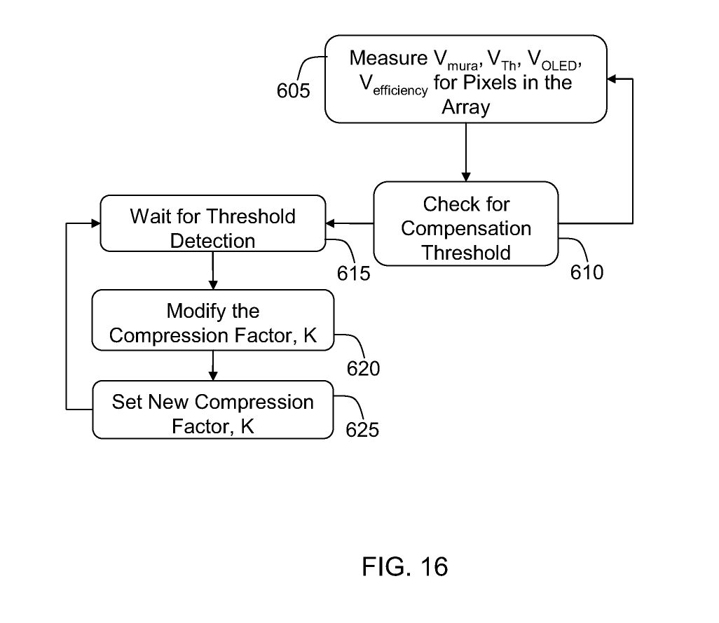

FIG. 16 is a flowchart illustrating a method for selecting the compression factor according to dynamic measurements of degradation data exceeding a threshold over a previous compensation. Measurements are taken from aspects of the pixel circuits of the pixels in the display 100 to measure Vₘᵤᵣₐ, V_{Th}, V_{OLED}, and V_{efficiency} (605) and compute V_{headroom} according to Expression 2. The difference between the value of V_{headroom} presently computed at time t2 is then compared to the value of V_{headroom} computed at an earlier time t1 by computing the difference (610). The difference is ΔV_{headroom}, and is calculated according to Expression 5: ΔV_{headroom}=(V_{headroom})ₜ₂−(V_{headroom})ₜ₁. In Expression 5, t1 is the last time used to adjust the compensation factor, K, and t2 is a present time. The subscripts in the right hand side of Expression 5 indicate a time of evaluation of the quantity in parentheses.

The calculated value of ΔV_{headroom} is then compared to a compensation threshold, Vₜₕᵣₑₛₕ (615). If ΔV_{headroom} exceeds Vₜₕᵣₑₛₕ, K is modified (620). If ΔV_{headroom} is less than or equal to Vₜₕᵣₑₛₕ, K is not modified. The value of K can be modified according to Expression 6: K_{new}=K_{old}/A−B, where K_{new} is the new value of K, K_{old} is the old value of K, and A and B are values set for applications and different technologies. For example, A and B can be set based on empirical results from experiments examining the characteristic degradation due to aging of pixel circuits similar to those used in the display 100 to drive OLEDs in each pixel. Similar measurements or user inputs can be used to set Vₜₕᵣₑₛₕ as well. The compression factor, K, is then set (625) for use in the compression and compensation algorithm, such as the compression algorithm illustrated in the data flow chart in FIG. 13. Degradation measurements continue to be measured (605), ΔV_{headroom} continues to be calculated (610), and K is updated according to Expression 6 whenever ΔV_{headroom} exceeds Vₜₕᵣₑₛₕ (515). According to an aspect of the present disclosure, the method of adjusting K shown in FIG. 5 is a dynamic method of adjusting K, because the value of K is updated over time according to degradation measurements gathered from the pixel circuits within the display 100.

Alternatively, the compression factor can be modified (620) according to Expression 3 based on the measured V_{headroom}. According to an aspect of the method provided in the flowchart shown in FIG. 16, the value of K is maintained until a threshold event occurs (615), when K is modified (620). Implementing the method provided in FIG. 16 for adjusting the compression factor, K, can result in K being decreased over time according to a stair step profile.

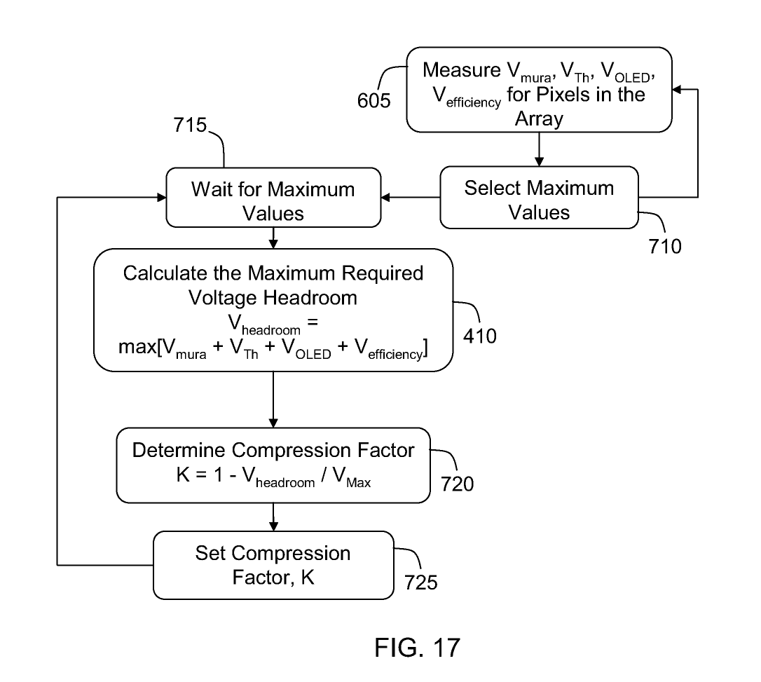

FIG. 17 is a flowchart illustrating a method for selecting the compression factor according to dynamic measurements of degradation data exceeding a previously measured maximum. Measurements are taken from aspects of the pixel circuits of the pixels in the display 100 to measure Vₘᵤᵣₐ, V_{Th}, V_{OLED}, and V_{efficiency} (605). The measurements of Vₘᵤᵣₐ, V_{Th}, V_{OLED}, and V_{efficiency} are referred to as degradation measurements. The maximum values of the degradation measurements are selected (710). The maximum values of the degradation can be selected according to Expression 2. The combination of measuring the degradation measurements (605) and selecting the maximum values (710) provides for ascertaining the maximum compensation applied to pixels within the display. The maximum values are compared to previously measured maximum values of previously measured degradation measurements (715). If the presently measured maximum values exceed the previously measured maximum values, V_{headroom} is calculated according to Expression 2 (410) based on the present degradation measurements. Next, the compression factor, K, is determined according to Expression 3 (720). The compression factor is set (725) and the maximum values are updated for comparison with new maximum values (715). The compression factor is set (725) for use in the compression and compensation algorithm, such as the compression algorithm illustrated in the data flow chart in FIG. 13. Similar to the method provided in FIG. 16, the method shown illustrated by the flowchart in FIG. 17 is a dynamic method of adjusting K based on degradation measurements continually gathered from the pixel circuits within the display 100.

The present disclosure can be implemented by combining the above disclosed methods for setting and adjusting the compression factor, K, in order to create an adequate amount of voltage headroom that allows for compensation to be applied to the digital data before it is passed to the data driver IC. For example, a method of setting and adjusting K according to FIG. 16 or FIG. 17 can also incorporate a user selected profile as in FIG. 15.

In an implementation of the present disclosure, the methods of selecting and adjusting the compression factor, K, provided in FIGS. 14 through 17 can be used in conjunction with the digital data manipulations illustrated in FIG. 13 to operate a display while maintaining the uniform luminosity of the display. In a configuration, the above described methods allow for maintaining the relative luminosity of a display by compensating for degradations to pixels within the display. In a configuration, the above described methods allow for maintaining the luminosity of a pixel in a display array for a given digital input by compensating for degradations within the pixel's pixel circuit.

The present disclosure describes maintaining uniform luminosity of an AMOLED display, but the techniques presented are not so limited. The disclosure is applicable to a range of systems incorporating arrays of devices having a characteristic stimulated responsive to a data input, and where the characteristic is sought to be maintained uniformly. For example, the present disclosure applies to sensor arrays, memory cells, and solid state light emitting diode displays. The present disclosure provides for modifying the data input that stimulates the characteristic of interest in order to maintain uniformity. While the present disclosure for compressing and compensating digital luminosity data to maintain a luminosity of an AMOLED display is described as utilizing TFTs and OLEDs, the present disclosure applies to a similar apparatus having a display including an array of light emitting devices.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

What is claimed is:

1. A method of compensating for a degradation of a pixel having a driving circuit for driving current through a light emitting device based on an input, the method comprising:
receiving luminosity data;
scaling the luminosity data by a compression factor to create compressed data;
compensating for the degradation of the pixel by adjusting the compressed data to create compensated data; and
supplying the driving circuit based on the compensated data.

2. The method of claim 1, wherein the scaling is carried out by multiplying the luminosity data by a constant integer to create resulting data with a greater number of bits, and multiplying the resulting data by the compression factor.

3. The method of claim 2, wherein the luminosity data is an eight-bit integer and the compressed data is a ten-bit integer.

4. The method of claim 1, wherein the driving circuit includes at least one thin film transistor (TFT).

5. The method of claim 4, wherein the at least one TFT is an n-type TFT.

6. The method of claim 4, wherein the at least one TFT is used to drive current through the light emitting device, and wherein the degradation is due to a voltage threshold of the at least one TFT or due to a shift in the voltage threshold of the at least one TFT.

7. The method of claim 1, wherein the light emitting device is an organic light emitting diode (OLED).

8. The method of claim 7, wherein the degradation is due to a bias voltage of the OLED or due to a shift in the bias voltage of the OLED.

9. The method of claim 7, wherein the degradation is due to a voltage required to compensate for an inefficiency of the OLED or due to a shift in the voltage required to compensate for the inefficiency of the OLED.

10. The method of claim 1, wherein the compression factor is determined based on a user selected profile and a usage time of the pixel.

11. The method of claim 1, wherein the compression factor is determined based on an estimation of degradation of the pixel and on a display requirement, and wherein the estimation is based on a design of hardware aspects of the pixel and of the driving circuit.

12. A method of operating a display having a plurality of pixels to compensate for a degradation of a pixel in the display, the pixel having a driving circuit for driving a current through a light emitting device based on an input, the input being supplied to the driving circuit by a display driver, the method comprising:
receiving luminosity data;
scaling the luminosity data by a compression factor to create compressed data;
compensating for a degradation of a pixel in the display by adjusting the compressed data based on the degradation to create compensated data; and
sending the compensated data to the display driver.

13. The method of claim 12, further comprising:
ascertaining a maximum compensation applied to the plurality of pixels; and
adjusting the compression factor based on the ascertained maximum compensation.

14. The method of claim 12, further comprising:
compensating for degradations of the plurality of pixels in the display by adjusting the compressed data based on the degradations to create compensated data;

14. The method of claim 13, wherein the adjusting is carried out by computing the ratio of the ascertained maximum compensation to a maximum assignable value of the inputs and updating the compression factor to be one minus the computed ratio.

15. The method of claim 12, wherein the luminosity data includes eight-bit integers and wherein the scaling is carried out by: multiplying the luminosity data by a constant integer to create resulting data with a greater number of bits, and multiplying the resulting data by the compression factor.

16. The method of claim 12, wherein at least one of the driving circuits includes at least one thin film transistor (TFT).

17. The method of claim 16, wherein the at least one TFT is an n-type TFT.

18. The method of claim 16, wherein the at least one TFT is used to drive current through at least one of the light emitting devices, and wherein the degradation is due to a voltage threshold of the at least one TFT or due to a shift in the voltage threshold of the at least one TFT.

19. The method of claim 12, wherein at least one of the light emitting devices is an organic light emitting diode (OLED).

20. The method of claim 19, wherein the degradation is due to a bias voltage of the OLED or due to a shift in the bias voltage of the OLED.

21. The method of claim 19, wherein the degradation is due to a voltage required to compensate for an inefficiency of the OLED or due to a shift in the voltage required to compensate for the inefficiency of the OLED.

22. The method of claim 12, wherein the compression factor is determined based on a user selected profile and a usage time of the display.

23. The method of claim 12, wherein the compression factor is determined based on an estimation of the degradation of the display and based on display requirements and the design of hardware aspects within the display.

24. A method of operating a display having a plurality of pixels to compensate for degradation of the plurality of pixels, wherein the plurality of pixels have driving circuits for driving currents through light emitting devices based on inputs, the method comprising:
operating the display according to a first compression factor by:
receiving a first set of luminosity data for the plurality of pixels;
scaling the first set of luminosity data by the first compression factor to create a first set of compressed data;
compensating for a first degradation of the plurality of pixels by adjusting the first set of compressed data based on a first set of offset increments to create a first set of compensated data; and
supplying the driving circuits based on the first set of compensated data;
determining a second compression factor based on a second degradation of the plurality of pixels; and
operating the display according to the second compression factor by:
receiving a second set of luminosity data for the plurality of pixels;
scaling the second set of luminosity data by the second compression factor to create a second set of compressed data;
compensating for the second degradation of the plurality of pixels by adjusting the second set of compressed data based on a second set of offset increments to create a second set of compensated data; and
supplying the driving circuits based on the second set of compensated data.

25. The method of claim 24, further comprising:
prior to operating the display according to the first compression factor, determining the first compression factor based on the first degradation of the plurality of pixels.

26. The method of claim 24, wherein the adjusting the first set of compressed data is carried out by adding the first set of offset increments to the first set of compressed data to create the first set of compensated data, and wherein the adjusting the second set of compressed data is carried out by adding the second set of offset increments to the second set of compressed data to create the second set of compensated data.

27. The method of claim 24, wherein the adjusting the first set of compressed data is carried out by subtracting the first set of offset increments from the first set of compressed data to create the first set of compensated data, and wherein the adjusting the second set of compressed data is carried out by subtracting the second set of offset increments from the second set of compressed data to create the second set of compensated data.

28. The method of claim 25, wherein the determining the first compression factor is carried out by ascertaining the maximum value in the first set of offset increments and computing the ratio of the ascertained maximum to a maximum assignable input value, and wherein the first set of offset increments is determined based on estimates of degradation of the plurality of pixels.

29. The method of claim 25, wherein the determining the first compression factor is carried out by ascertaining the maximum value in the first set of offset increments and computing the ratio of the ascertained maximum to a maximum assignable input value, and wherein the first set of offset increments is determined based on measurements of degradation of the plurality of pixels.

30. The method of claim 24, wherein the determining the second compression factor is carried out by ascertaining the maximum value in the second set of offset increments and computing the ratio of the ascertained maximum to a maximum assignable input value, and wherein the second set of offset increments is determined based on estimates of degradation of the plurality of pixels.

31. The method of claim 24, wherein the determining the second compression factor is carried out by ascertaining the maximum value in the second set of offset increments and computing the ratio of the ascertained maximum to a maximum assignable input value, and wherein the second set of offset increments is determined based on measurements of degradation of the plurality of pixels.

32. The method of claim 24, wherein the first set of luminosity data and second set of luminosity data include eight-bit integers, and wherein the scaling the first set of luminosity data is carried out by:
multiplying the first set of luminosity data by a constant integer to create a first set of resulting data that includes integers having a number of bits greater eight; and
multiplying the first set of resulting data by the first compression factor, and wherein the scaling the second set of luminosity data is carried out by:
multiplying the second set of luminosity data by the constant integer to create a second set of resulting data that includes integers having a number of bits greater eight; and
multiplying the second set of resulting data by the second compression factor.

33. A display degradation compensation system for compensating for a degradation of a plurality of pixels in a display, wherein the plurality of pixels have driving circuits for driving currents through light emitting devices, the display degradation compensation system comprising:
a digital data processor module for receiving a luminosity data, compressing the luminosity data according to a compression factor, and compensating for the degradation of the plurality of pixels by adjusting the compressed data to create compensated data; and
a display driver for receiving the compensated data and supplying the inputs to the driving circuits, the driving circuits being configured to deliver the driving currents to the light emitting devices based on the received compensated data.

34. The display degradation compensation system of claim 33, wherein the adjusting the compressed data is carried out according to a measurement of the degradation of the plurality of pixels.

35. The display degradation compensation system of claim 33, wherein the digital data processor module includes a digital adder for adjusting the compressed data to create compensated data.

36. The display degradation compensation system of claim 33, further comprising:
a compensation module for determining the compression factor.

37. The display degradation compensation system of claim 36, wherein the compensation module is configured to determine the compression factor according to a function including a measurement of the degradation of the plurality of pixels.

38. The display degradation compensation system of claim 36, wherein the compensation module is configured to dynamically adjust the compression factor according to an input specified by a user and according to a usage time of the display.

39. The display degradation compensation system of claim 36, wherein the compensation module is configured to dynamically adjust the compression factor according to a function including a measurement of the degradation of the plurality of pixels.

40. The display degradation compensation system of claim 33, wherein the digital data processor module is configured to receive eight-bit luminance data and output ten-bit compensated data.

41. The display degradation compensation system of claim 33, wherein at least one of the light emitting devices is an organic light emitting diode.

42. The display degradation compensation system of claim 33, wherein at least one of the driving circuits includes at least one thin film transistor.

43. A method of operating a display having a plurality of pixels to compensate for a degradation of the plurality of pixels, wherein the plurality of pixels have driving circuits for driving currents through light emitting devices based on inputs, the method comprising:
receiving a video signal having a set of grayscale values for the plurality of pixels;
compressing the grayscale values to a range less than an available range and reserving a remaining amount of grayscale values for adjustments; and
outputting the compressed grayscale values to a display driver for programming the driving circuits of the plurality of pixels.

44. The method of claim 43, wherein the set of grayscale values is eight-bit data, and wherein the compressing is carried out according to a grayscale compression algorithm that translates the set of compressed grayscale values having a range of 200 values.

45. The method of claim 43, wherein the remaining amount of grayscale values are reserved at a high end of the available range to provide adjustments that increase the luminosity of adjusted pixels.

46. The method of claim 43, wherein the remaining amount of grayscale values are reserved at a low end of the available range to provide adjustments that decrease the luminosity of adjusted pixels.

47. The method of claim 43, further comprising:
adjusting a value in the set of grayscale values corresponding to at least one of the plurality of pixels according to a decreasing brightness algorithm.

48. The method of claim 43, further comprising:
adjusting a value in the set of grayscale values corresponding to at least one of the plurality of pixels according to a constant brightness algorithm.

49. A system for compensating for non-uniformities in a display having a plurality of pixels, at least one of the plurality of pixels including a pixel circuit having a light emitting device, the pixel circuit configured to drive the pixel based on luminance data; the system comprising:
a module for modifying the pixel data applied to one or more than one pixel, the module including:
an estimating module for estimating a degradation of a first pixel circuit based on measurement data read from the first pixel circuit;
a grayscale compression module for compressing the luminance data according to a grayscale compression algorithm to reserve grayscale values; and
a compensating module for correcting the compressed luminance data applied to the first or a second pixel circuit based on the estimation of the degradation of the first pixel circuit; and
a display driver for receiving the corrected luminance data and supplying the pixel circuit with an analog voltage or current based on the corrected luminance data.

50. The system of claim 49, wherein the grayscale compression module transforms the luminance data so as to use luminance values less than those of the original luminance data.

51. The system of claim 49, wherein the luminance data is eight-bit data, and wherein the compressing is carried out in the grayscale compression module to transform the luminance data to a range of 200 values.

52. The method of claim 49, wherein the reserved grayscale values are reserved at a high end of an available range to allow for providing corrections to the compressed luminance data that increase the luminosity of corrected pixels.

53. The method of claim 49, wherein the reserved grayscale values are reserved at a low end of an available range to allow for providing corrections to the compressed luminance data that decrease the luminosity of corrected pixels.

54. The method of claim 49, wherein the compensating module corrects the luminance data according to a decreasing brightness algorithm.

55. The method of claim 49, wherein the compensating module corrects the luminance data according to a constant brightness algorithm.
